(19) United States
(12) Patent Application Publication
(10) Pub. No.: US 2009/0219969 A1
(43) Pub. Date: Sep. 3, 2009

(54) SUBSTRATE SURFACE TEMPERATURE MEASUREMENT METHOD, SUBSTRATE PROCESSING APPARATUS USING THE SAME, AND SEMICONDUCTOR DEVICE MANUFACTURING METHOD

(75) Inventor: Takeshi Yamamoto, Fujisawa-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/396,564

(22) Filed: Mar. 3, 2009

(30) Foreign Application Priority Data
Mar. 3, 2008 (JP) 2008-051931

(51) Int. Cl. G01K 17/00; H01L 21/66

(52) U.S. Cl. 374/29; 438/14; 374/E17.001; 257/E21.521

(57) ABSTRACT

The expansion amount of a substrate (106) is measured using a scope (115a, 115b) which observes the edge surface of the substrate (106). The temperature of the neutral plane of the substrate (106) is calculated using the expansion amount of the substrate (106). A heat flux in the substrate (106) is measured using a heat flux sensor (110). The temperature difference between the neutral surface and upper surface of the substrate (106) is calculated from the measured heat flux and the heat resistance of the substrate (106). The temperature of the surface of the substrate (106) is obtained using the temperature difference and the temperature of the neutral plane of the substrate.

### BACKGROUND OF THE INVENTION

1. Field of the Invention

The present invention relates, in an apparatus that heats and cools a substrate in a process of manufacturing an electronic device such as a semiconductor integrated circuit and a display device electron source, to a substrate surface temperature measurement method which measures the substrate surface temperature in-situ, a substrate processing apparatus which uses this method, and a semiconductor device manufacturing method.

2. Description of the Related Art

A semiconductor integrated circuit manufacturing process includes various types of annealing processes such as baking in photolithography, film formation, and ashing. In such an annealing process, conventionally, a target substrate is heated using a halogen lamp arranged to oppose the target substrate, or a heater incorporated in a support body that supports the target substrate.

In this case, a radiation thermometer is arranged on a side opposite to the halogen lamp across the target substrate and measures the temperature of the target substrate in noncontact with it. The light quantity of the halogen lamp is adjusted on the basis of the measurement result, thus controlling the heating temperature for the target substrate.

Regarding measurement of the substrate surface temperature, a heat flux meter and temperature sensor are arranged near the lower surface of the target substrate and measure the surface temperature using the heat resistance from their positions to the upper surface of the substrate (see Japanese Patent Laid-Open No. 2002-170775).

Alternatively, a window is formed in part of the wall of a chamber serving as a vacuum processing chamber for the target substrate. The surface temperature of the target substrate is measured outside the wall of the chamber using a radiation thermometer (see Japanese Patent Laid-Open No. 60-253939).

Alternatively, a contact type sensor such as a thermocouple is brought into direct contact with the surface of the substrate and measures the surface temperature.

Alternatively, a contact type distance sensor is set on the side surface of the substrate. The average temperature of the substrate is obtained by measuring the expansion amount of the substrate, and the obtained average temperature is used as the surface temperature (see Japanese Patent Laid-Open No. 7-27634).

A radiation thermometer used for temperature measurement is advantageous in that it can measure the surface temperature of an object in noncontact with it by measuring light having a wavelength distribution and radiated from the object surface using a sensor such as a thermopile.

When measuring the substrate surface using the radiation thermometer, however, the emissivity changes depending on the composition and surface state of the substrate. To accurately measure the surface temperature of the substrate, the obtained temperature must be calibrated for each composition and each surface state of the substrate. An error may occur in measurement when an observation window to observe the substrate is contaminated with a film forming gas. Also, as the radiation thermometer itself is expensive, it increases the cost of the substrate processing apparatus itself.

In particular, when using the radiation thermometer in a film formation apparatus, the calibration parameter must be changed in accordance with a change in film formation state that changes constantly. It is, however, very difficult to accurately obtain the thickness of the film during formation and the composition of the film. Therefore, it is difficult to set the calibration parameter correctly.

A prior art employing a radiation thermometer will be described with reference to FIG. 9.

Referring to FIG. 9, reference numeral 101 denotes a vacuum vessel; 102, a source gas supply device which supplies gas as a film forming material; 103, a valve; 104, a vacuum pump; 105, a flow controller which adjusts the concentration of the source gas; and 106, a substrate as a processing target. Reference numeral 107 denotes an electrostatic chuck which fixes the substrate 106 at a predetermined position; 108, a substrate stage which suppresses deformation of the electrostatic chuck 107; and 109, an attaching member which connects the substrate stage 108 to the vacuum vessel 101. Reference numeral 111 denotes a halogen heater which heats the surface of the substrate 106 with radiation heat; 112, an attaching member which connects the heater 111 to the vacuum vessel 101; and 113, a halogen heater controller. Also, reference numeral 301 denotes a radiation thermometer set outside the vacuum vessel 101; and 302, an extraction window which transmits radiation from the substrate 106. The radiation thermometer 301 can measure the radiation transmitted through the extraction window 302.

When the radiation thermometer is used in this manner, generally, even if the surface temperature of the substrate 106 stays the same, the radiant quantity measured by the radiation thermometer 301 changes in accordance with a change in composition of the film formed on the surface of the substrate 106.

The inner side of the extraction window 302 is constantly contaminated by the source gas and the cleaning is required. Accordingly, the measured radiant quantity must be corrected in accordance with the light transmittance of the extraction window 302.

Beams transmitted through the extraction window 302 include radiation from the substrate 106 as well as light reflected by the wall of the vacuum vessel 101. Also, light from the halogen heater 111 may be directly reflected by the substrate 106, reach the extraction window 302 in the form of stray light, and be transmitted through the extraction window 302. A countermeasure for this problem is also necessary.

In this manner, although measurement using the radiation thermometer is advantageous in that it allows noncontact observation, the accuracy may be degraded by various measurement errors, and the radiation thermometer itself is expensive.

As another technique, a method of obtaining the substrate temperature by conversion from the expansion amount of the substrate is also available. With this method, the average temperature of the substrate can be calculated. If, however, a temperature distribution exists in the substrate, the temperature difference between the average temperature and surface temperature of the substrate increases, thus increasing the error.

The conventional technique of obtaining the substrate temperature by conversion from the expansion amount of the substrate will be described with reference to FIG. 10.

Referring to FIG. 10, reference numeral 401 denotes a lamp; 402, a substrate; 403, a movable quartz pin; 404, an optical micrometer; and 405, a support pin. Reference numeral 406 denotes a process chamber; 407, a lamp power control unit; 408, a displacement/temperature converter; and 409, a process recipe. FIG. 10 is a plan view of the substrate surface.

In the apparatus of FIG. 10, light emitted by the lamp 401 heats the substrate 402 placed in the process chamber 406. When the substrate 402 is heated, it expands. As the support pin 405 restricts one side of the substrate 402, the expansion amount of the substrate 402 appears as the moving amount itself of the movable quartz pin 403 provided to the substrate 402. The expansion amount of the substrate 402 is calculated by reading the moving amount of the movable quartz pin 403 by the optical micrometer 404. Upon reception of the calculated expansion amount, the displacement/temperature converter 408 calculates the temperature of the substrate 402 and sends it to the lamp power control unit 407. The lamp power control unit 407 controls the lamp 401 by referring to the received substrate temperature and the process recipe 409.

As the movable quartz pin 403 is in contact with the substrate 402, however, heat of the substrate 402 drifts to the movable quartz pin 403 and heats it, and accordingly the movable quartz pin 403 itself expands. As a result, the moving amount of that surface of the movable quartz pin 403 which faces the optical micrometer 404 differs from the moving amount of the end face of the substrate 402 which is not in contact with the movable quartz pin 403. This causes an error in temperature measurement.

When a temperature distribution exists in the substrate 402, it is the average temperature of the entire substrate that can be calculated from the expansion amount of the substrate, and the surface temperature of the substrate cannot always be measured. For example, as shown in FIG. 10, when heating the substrate 402 using the lamp from the upper surface side, the heat drifts to the lower surface of the substrate 402.

Alternatively, when heating the substrate 402 using the lamp from the lower surface side, the heat drifts to the upper surface side. Consequently, a temperature difference occurs between the upper and lower surfaces of the substrate 402. It is thus difficult to accurately measure the surface temperature of the substrate only from the expansion amount of the substrate.

As another technique, a method is available which measures by bringing a contact type sensor such as a thermocouple in direct contact with the substrate. When bringing the sensor into contact with the substrate surface in this manner, or when the substrate expands by a temperature change in the substrate, it is difficult to maintain the contact state of the sensor with the substrate. Also, as the thermocouple itself is heated by the heater, an error may occur. Since the film is not formed on that portion of the substrate which is in contact with the sensor, the substrate is partly wasted.

### SUMMARY OF THE INVENTION

It is an object of the present invention to provide a surface temperature measurement method that can solve one of the problems described above, and a substrate processing apparatus which utilizes this method. It is another object of the present invention to improve the measurement accuracy of the substrate surface temperature.

According to one aspect of the present invention, there is provided a substrate surface temperature measurement method comprising:

a measurement step of measuring an expansion amount of a substrate; and

a surface temperature calculation step of calculating a temperature of a neutral plane of the substrate using the expansion amount of the substrate, calculating a temperature difference between the neutral plane and an upper surface of the substrate from a heat flux and heat resistance of the substrate, and obtaining a temperature of the upper surface of the substrate using the temperature difference and the temperature of the neutral plane of the substrate.

According to another aspect of the present invention, there is provided a substrate processing apparatus comprising:

heating means for heating a substrate;

control means for controlling the heating means;

expansion amount measurement means for measuring an expansion amount of the substrate; and

heat flux measurement means for measuring a heat flux in the substrate,

wherein the control means calculates a temperature of a neutral plane of the substrate using the expansion amount measured by the expansion amount measurement means, calculates a temperature difference between the neutral plane and an upper surface of the substrate from the heat flux measured by the heat flux measurement means and a heat resistance, obtaining a temperature of the upper surface of the substrate using the temperature difference and the temperature of the neutral plane of the substrate, and controls the heating means on the basis of the temperature of the upper surface.

According to still another aspect of the present invention, there is provided a substrate processing apparatus comprising:

a substrate support body which supports a substrate;

substrate heating means provided to the substrate support body;

heat-insulating means for covering the substrate support body;

control means for controlling the substrate heating means; and

expansion amount measurement means for measuring an expansion amount of the substrate,

wherein the control means

calculates a temperature of a neutral plane of the substrate using the expansion amount measured by the expansion amount measurement means,

calculates a heat flux in the substrate from an energy supplied to the heating means, and

calculates a temperature difference between the neutral plane and an upper surface of the substrate from the calculated heat flux and a heat resistance, obtains a temperature of the upper surface of the substrate using the temperature difference and the temperature of the neutral plane of the substrate, and controls the heating means on the basis of the temperature of the upper surface.

According to yet another aspect of the present invention, there is provided a semiconductor device manufacturing method comprising a step of measuring a surface temperature of a substrate using a substrate surface temperature measurement method according to one aspect of the present invention.

According to the present invention, the measurement accuracy of the substrate surface temperature can improve.

Further features of the present invention will become apparent from the following description of exemplary embodiments with reference to the attached drawings.

### BRIEF DESCRIPTION OF THE DRAWINGS

FIG. 1 is a view schematically showing the arrangement of an apparatus according to the first embodiment of the present invention;

FIG. 2 is a view for explaining how to obtain the surface temperature of a substrate according to the first embodiment;

FIG. 3 is a graph for explaining the temperature gradient in the substrate;

FIG. 4 is a schematic view showing an arrangement of a heat flux sensor employed in the apparatus of the present invention;

FIG. 5 is a view schematically showing the arrangement of an apparatus according to the second embodiment of the present invention;

FIG. 6 is a view schematically showing the arrangement of an apparatus according to the third embodiment of the present invention;

FIG. 7 is a view for schematically explaining alignment marks formed on the substrate as the alignment marks are observed by an alignment scope in the third embodiment;

FIG. 8 is a view schematically showing the arrangement of an apparatus according to the fourth embodiment of the present invention;

FIG. 9 is a view schematically showing the arrangement of the first apparatus of the background art; and

FIG. 10 is a view schematically showing the arrangement of the second apparatus of the background art.

### DESCRIPTION OF THE EMBODIMENTS

In the present invention, the surface temperature of a substrate is measured using the expansion amount of the substrate, the heat flux flowing through the substrate, and the heat resistance of the substrate. In this specification, the upper surface of the substrate refers to a surface which is to undergo a process such as film formation, the lower surface of the substrate refers to a surface on a side opposite to the upper surface, and the edge surface of the substrate refers to any other surface of the substrate than the upper and lower surfaces.

The expansion amount of the substrate can be measured by detecting the edge surface of the substrate by a noncontact sensor, e.g., a distance measuring sensor using light, or by detecting a mark formed on the substrate by an alignment scope having a mark image recognition function.

At this time, when expansion of a scope stage on which the alignment mark is to be placed influences the measurement accuracy, the coefficient of linear expansion of the scope stage may be obtained in advance, and the temperature may be measured whenever necessary, thus canceling the influence of expansion of the scope stage.

In this case, it is significant that the coefficient of linear expansion of the target substrate rarely changes during the process of the substrate. In general, the substrate has a thickness of approximately 1 mm, whereas the thickness of a layer formed on the substrate is as small as approximately several μm. Even when the coefficient of linear expansion of the entire substrate is substituted by the coefficient of linear expansion of the substrate outsides the layer, the error is very small.

Therefore, the average temperature of the substrate can be calculated from the expansion amount and the coefficient of linear expansion of the substrate. In addition, the coefficient of linear expansion of the substrate is determined by the physical properties of the substrate, which is very convenient in obtaining the absolute temperature. This alone, however, does not enable calculation of the surface temperature of the surface when a heat flux exists in the substrate to form a temperature distribution. For this reason, the temperature gradient in the substrate is calculated by measuring the heat flux that forms the temperature distribution in the substrate. When the quantity of heat dissipating from the edge portion of the substrate is negligibly small, the temperature gradient in the substrate can be regarded constant. Thus, the average temperature of the substrate coincides with the temperature of the neutral plane of the substrate. The present invention is aimed at determining, by utilizing this fact, the absolute temperature of the substrate surface through addition and subtraction of the average temperature of the substrate (that is, the temperature of the neutral plane of the substrate) obtained from the expansion amount of the substrate and the temperature gradient calculated from the heat flux (that is, the relative temperature difference between the neutral plane and upper surface of the substrate).

At this time, the substrate may be heated using a halogen heater or the like from its upper surface side, or using a heater from its lower surface. Since the substrate as a whole forms a thin plate, heat dissipating from the edge surface of the substrate is negligible. Therefore, in any case, the heat flux flowing through the substrate can be approximately regarded to be equal to the heat flux flowing through a stage that supports the substrate, or through an electrostatic chuck.

In this manner, the temperature distribution (temperature gradient) in the substrate can be calculated from the magnitude of the measured heat flux and the heat resistance of the substrate. The surface temperature of the substrate can be obtained through addition or subtraction of the temperature gradient and the average temperature of the substrate calculated from the expansion amount.

Note that the “neutral plane” of the substrate refers to a virtual plane which is at the equal distance from the upper and lower surfaces of the substrate.

The embodiments of the present invention will now be described with reference to the accompanying drawings.

### First Embodiment

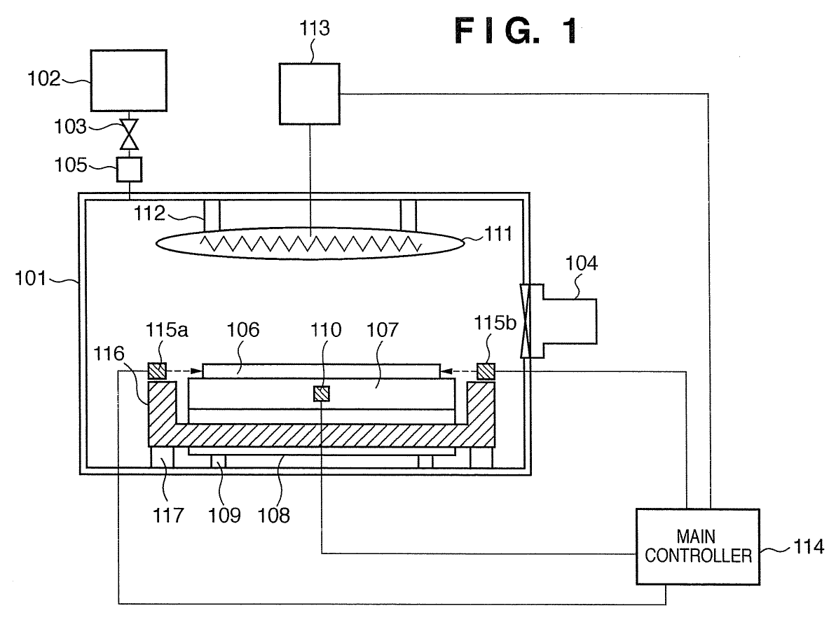

FIG. 1 schematically shows the arrangement of a thermal CVD apparatus according to the first embodiment of the present invention.

A substrate processing apparatus employed as the thermal CVD apparatus of this embodiment includes a vacuum vessel 101 and forms a film on a substrate 106 in the vacuum vessel 101. A source gas supply device 102 and vacuum pump 104 are provided to the vacuum vessel 101. The source gas supply device 102 supplies a gas as the source of the film to the vacuum vessel 101. A supply path for the source gas is provided with a valve 103 and a flow controller 105 which adjusts the concentration of the source gas.

The vacuum vessel 101 is provided with an electrostatic chuck 107 and substrate stage 108 at its inner bottom. The electrostatic chuck 107 fixes the substrate 106 at a predetermined position. The substrate stage 108 suppresses deformation of the electrostatic chuck 107. The substrate stage 108 is connected to the vacuum vessel 101 through an attaching member 109. The substrate stage 108 is formed of a sufficiently rigid member. Thus, even if the vacuum vessel 101 is deformed by heat or a change in vacuum degree, the deformation will not influence the electrostatic chuck 107. A structure utilizing spring elasticity is interposed between the substrate stage 108 and attaching member 109.

A halogen heater 111 which heats the substrate 106 is located at that portion of the inner ceiling of the vacuum vessel 101 which opposes the surface of the substrate 106. The halogen heater 111 is connected to the vacuum vessel 101 through an attaching member 112. A heater controller 113 controls the temperature of the halogen heater 111 and the quantity of heat to be supplied. The heater controller 113 is connected to a main controller 114.

The electrostatic chuck 107 is provided with a heat flux sensor 110 serving as a heat flux detection means which detects a heat flux drifting in the electrostatic chuck 107 in a direction perpendicular to the substrate surface. Scopes 115a and 115b serving as distance measuring sensors are set at portions that respectively face the opposing edge surfaces of the substrate 106. The scopes 115a and 115b observe the edge positions of the substrate 106 and measure the distances to the edge surfaces. The heat flux sensor 110 and scopes 115a and 115b are connected to the main controller 114 and inform the main controller 114 of their measurement information.

The respective scopes 115a and 115b are fixed to a scope stage (support body) 116. The scope stage 116 is connected to the vacuum vessel 101 through an attaching member 117. The scope stage 116 is formed of a sufficiently rigid member so deformation in shape of the vacuum vessel 101 will not influence the scope stage 116. A structure utilizing spring elasticity is interposed between the scope stage 116 and attaching member 117.

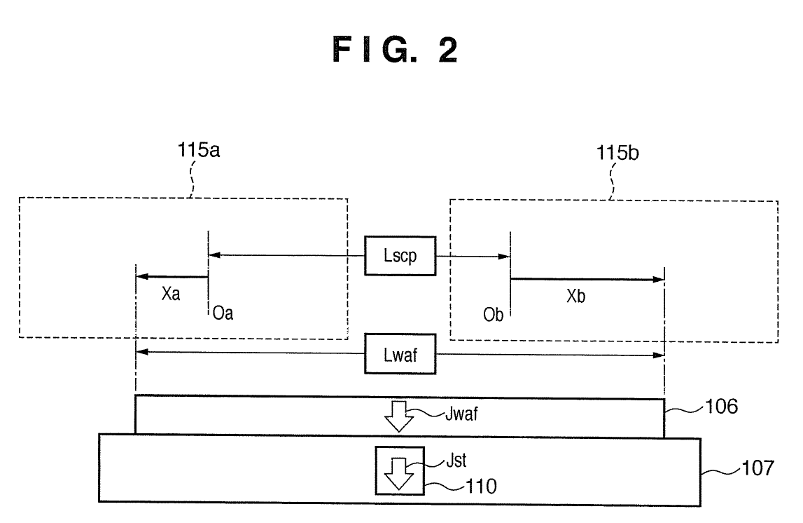

A method of measuring the surface temperature of the substrate 106 will be described in more detail with reference to FIG. 2. FIG. 2 includes the main part of the apparatus of FIG. 1 together with variables necessary in the following description.

0a, 0b, Lscp, Xa, Xb, and Lwaf are defined as follows. Namely, 0a and 0b represent scope position references; Lscp, the distance between the position references of the scopes 115a and 115b; Xa and Xb, the amounts of displacement of the edge surfaces of the substrate 106 which are measured by the corresponding scopes 115a and 115b, respectively (an outward direction from the substrate with reference to the scope position references 0a and 0b as origins (reference points) is determined as the positive direction); and Lwaf, a substrate length.

At this time, by using the distance Lscp between the scope position references and the two scope measurement values Xa and Xb, the substrate length Lwaf can be expressed as:

Lwaf=Lscp+Xa+Xb (1)

Also, variables T0w, Lwaf0, Twaf, and ρwaf are defined as follows. Namely,

T0w: the temperature at which the substrate reference length is measured

Lwaf0: the substrate length Lwaf at the temperature T0w

Twaf: the average substrate temperature

ρwaf: the coefficient of linear expansion of the substrate 106

At this time, the substrate length Lwaf can also similarly be expressed as:

Lwaf=Lwaf0*(1+ρwaf*(Twaf−T0w)) (2)

Thus, from the above equations (1) and (2), the substrate average temperature Twaf can be expressed as:

Twaf=((Lscp+Xa+Xb)/Lwaf0−1)/ρwaf+T0w (3)

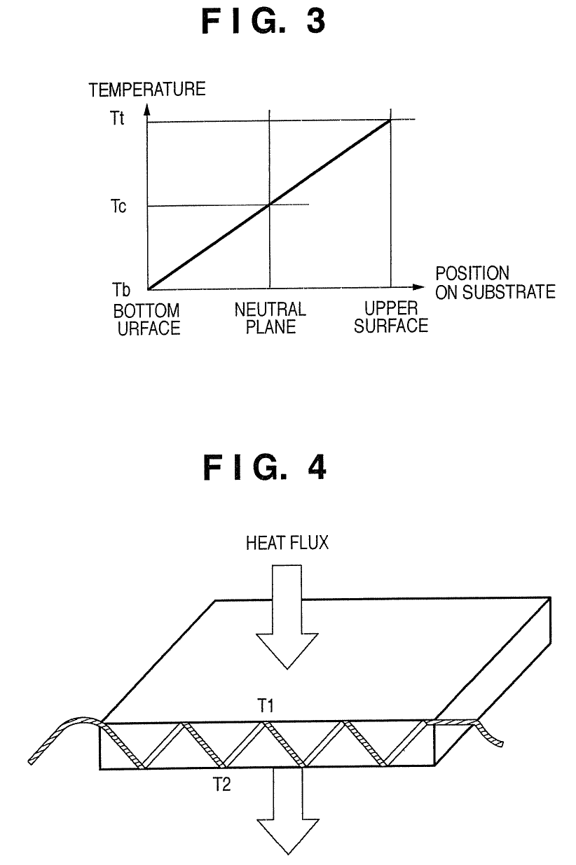

Referring to FIGS. 2 and 3, note that

Jst: the heat flux [W/cm²] flowing through the electrostatic chuck 107

Jwaf: the heat flux [W/cm²] flowing through the substrate 106 (for both Jst and Jwaf, a direction from the upper surface to the lower surface of the substrate is defined as the positive direction)

Tb: the temperature of the lower surface (the surface on the substrate stage 108 side) of the substrate

Tc: the temperature of the neutral plane of the substrate

Tt: the temperature of the upper surface of the substrate

In FIG. 2, part of the heat supplied by the heater 111 is dissipated from the substrate 106 through the electrostatic chuck 107. At this time, the heat flux Jst flowing through the electrostatic chuck 107 can be measured by the heat flux sensor 110. As the substrate 106 is chucked by the electrostatic chuck 107, the heat flux Jwaf flowing through the substrate 106 can be substituted by the measured heat flux Jst.

Regarding the heat flow described above, a temperature gradient is formed in the substrate 106 in accordance with the heat flux Jwaf flowing through the substrate. The heat flux in the substrate 106 can, however, be considered to be almost constant at all locations in the direction of thickness of the substrate. Hence, a linear temperature gradient is formed from the upper surface to the lower surface of the substrate. The temperature gradient can be considered to be constant as shown in FIG. 3. Then, the substrate average temperature Twaf is equal to the temperature Tc of the neutral plane of the substrate.

Hence,

Tc=Twaf (4)

Also, the temperature difference between the neutral plane and upper surface of the substrate is given by:

Tt−Tc=Jwaf*R (5)

where R is the heat resistance [K·cm²/W] from the neutral plane to the upper surface of the substrate.

Therefore, using the above equations (1), (2), (3), and (4), the substrate upper surface temperature Tt can be calculated as:

$$\begin{matrix}Tt = Tc + Jwaf * R \\ = Twaf + Jwaf * R \\ = ( ( Lscp + Xa + Xb ) \text{/} Lwaf 0 - 1 ) \text{/} ρwaf + T 0 w + Jst * R\end{matrix} \qquad ( 6 )$$

This will be described with reference to the apparatus in FIG. 1. While processing the substrate, the measurement values Xa and Xb indicating the expansion amount of the substrate 106 are obtained by the scopes 115a and 115b. The main controller 114 is informed of the measurement values Xa and Xb. Based on the expansion amount, the initial length (substrate reference length Lwaf0) of the substrate 106 which is measured in advance, the temperature T0w at which Lwaf0 is measured, and the coefficient ρwaf of linear expansion of the substrate 106, the main controller 114 calculates the temperature Tc (substrate average temperature Twaf) of the neutral plane of the substrate 106 (see equations (3) and (4)). As the substrate reference length Lwaf0, temperature T0w, and coefficient ρwaf of linear expansion are fixed parameters, they need to be stored in the main controller 114 in advance before processing the substrate.

Simultaneously with the Tc calculation step, the heat flux sensor 110 measures the heat flux Jwaf in the substrate 106 (substituted by the heat flux Jst in the electrostatic chuck 107). The main controller 114 is informed of the heat flux Jst. Based on the measured heat flux Jst and the heat resistance R of the substrate 106 which is input in advance, the main controller 114 calculates the temperature difference (Tt−Tc) between the neutral plane and upper surface of the substrate 106 (see equation (5)). Regarding the heat resistance R of the substrate 106, if the substrate is a wafer product to sell or the like, its heat resistance value is known. This value is stored in the main controller 114 in advance.

Finally, using the calculated temperature Tc of the neutral plane of the substrate 106 and the temperature difference (Tt−Tc) between the neutral plane and upper surface of the substrate 106, the main controller 114 obtains the surface temperature Tt of the substrate. The quantity of heat of the halogen heater 111 is adjusted in accordance with this measurement result.

In this manner, with the apparatus of this embodiment, the substrate surface temperature Tt can be calculated using the measurement values Xa and Xb of the scopes 115a and 115b and the measurement value Jst of the heat flux sensor 110.

FIG. 4 is a schematic view showing a practical example of the heat flux sensor 110.

A heat flux sensor functions as follows. Thermocouples are disposed on the upper and lower surfaces, respectively, of the plate-like body of the heat flux sensor having a heat resistance. A temperature difference (T1−T2) occurring when a heat flux flows through the thermocouples is measured, thus measuring the magnitude of the heat flux. The temperature difference (T1−T2) measured by the thermocouples on the heat flux sensor surfaces is equal to the product of the heat flux (W/cm²) and the heat resistance (K·cm²/W). If the heat resistance is obtained in advance, the heat flux is obtained from the measured temperature difference. As a scheme to improve the sensitivity, as shown in FIG. 4, thermocouples are connected in series in a heat flux sensor.

### Second Embodiment

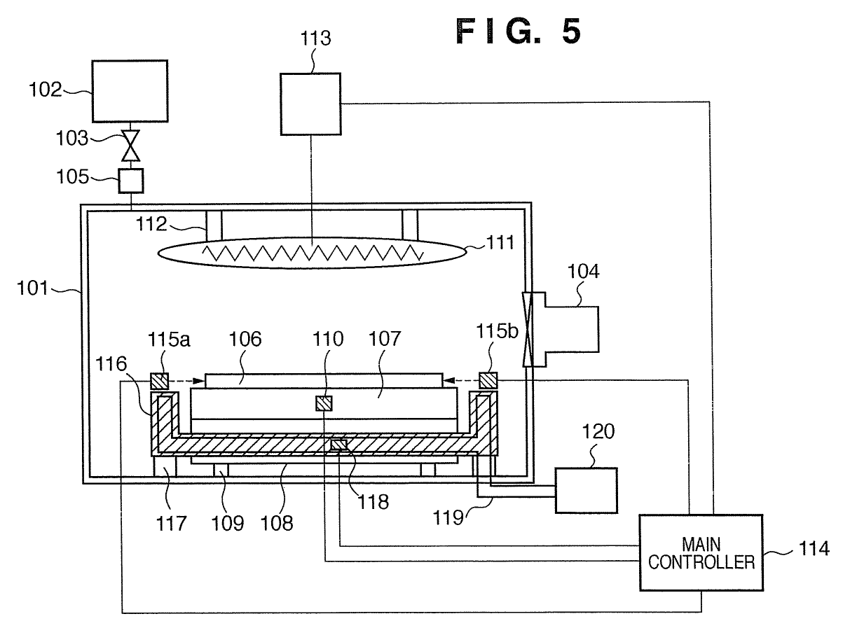

FIG. 5 schematically shows the arrangement of a thermal CVD apparatus according to the second embodiment of the present invention.

The apparatus of this embodiment is obtained by adding a scope stage temperature sensor 118 to the arrangement of FIG. 1. The scope stage temperature sensor 118 serves as a support body temperature detection means for detecting the temperature of a scope stage 116. In addition, a scope stage temperature controlling pipe 119 and scope stage temperature controller 120 are added. The scope stage temperature controlling pipe 119 is laid in the scope stage 116 to adjust the temperature of the scope stage 116. The scope stage temperature controller 120 controls the circulation of a refrigerant flowing in the pipe 119.

As the refrigerant circulates in the scope stage temperature controlling pipe 119, the temperature nonuniformities in the scope stage 116 can be decreased more than in a scope stage not provided with a scope stage temperature controlling pipe 119. Hence, the measurement error of the scope stage temperature sensor 118 can be suppressed.

The scope stage temperature sensor 118 is connected to a main controller 114 and informs it of the temperature of the scope stage 116.

In the above arrangement, assume that the temperature of the scope stage 116 changes due to heat exchange with the ambient atmosphere and that the length of the scope stage 116 itself changes. In this case as well, a length Lwaf of a substrate 106 and a substrate surface temperature Tt can be calculated accurately. This will be described below in detail.

Note that

T0s: the temperature at which the scope reference length is measured

Tscp: the scope stage temperature measured by the scope stage temperature sensor 118

Lscp0: a distance Lscp between the position references of scopes 115a and 115b, respectively, at the temperature T0s

ρscp: the coefficient of linear expansion of the scope stage 116

Then, a distance Lscp between the scope position references can be expressed as:

Lscp=Lscp0*(1+ρscp*(Tscp−T0s)) (7)

When equation (7) is combined with equation (6) described above, the substrate surface temperature Tt is calculated as:

Tt=(((Lscp0*(1+ρscp*(Tscp−T0s)))+Xa+Xb)/Lwaf0−1)/ρwaf+T0w+Jwaf*R (8)

In this manner, with the apparatus of FIG. 5, the substrate surface temperature Tt can be calculated using measurement values Xa and Xb of the scopes 115a and 115b, respectively, a measurement value Jst of a heat flux sensor 110, and the scope stage temperature (Tscp).

### Third Embodiment

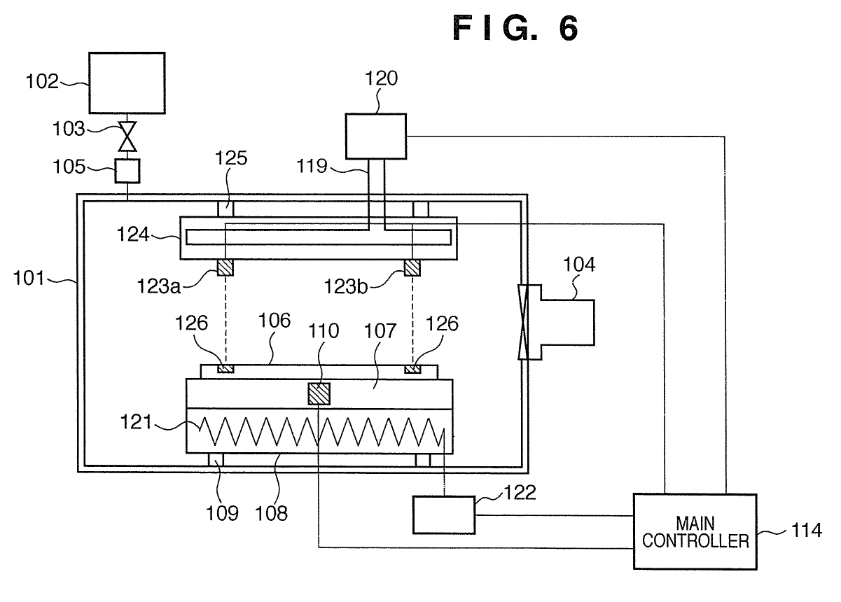

FIG. 6 schematically shows the arrangement of a thermal CVD apparatus according to the third embodiment of the present invention. In the description of this embodiment, the same constituent components as those of the apparatuses shown in FIGS. 1 and 5 are denoted by the same reference numerals, and a repetitive description will be omitted.

In the third embodiment, no halogen heater (see reference numeral 111 in FIGS. 1 and 2) is provided above the substrate surface. As shown in FIG. 6, a heater 121 arranged in a substrate stage 108 heats a substrate 106. The heater 121 is connected to a heater controller 122. The heater controller 122 is connected to a main controller 114.

The upper surface of the substrate 106 has alignment marks 126 at a plurality of portions. The positions of the alignment marks 126 can be detected by alignment scopes 123a and 123b above them. The alignment scopes 123a and 123b are attached to a scope stage 124. The scope stage 124 is connected to the ceiling of a vacuum vessel 101 through an attaching member 125. A scope stage temperature controlling pipe 119 is laid in the scope stage 124. A scope stage temperature controller 120 controls the circulation of a refrigerant flowing in the controlling pipe 119.

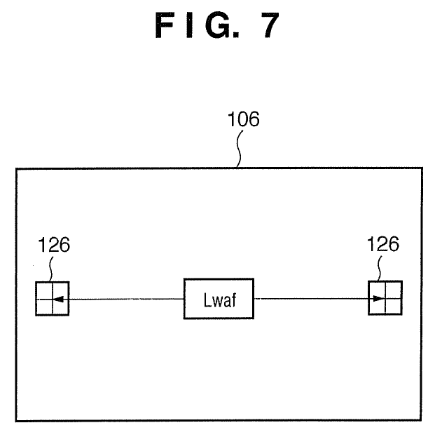

FIG. 7 schematically shows how the alignment marks 126 formed on the substrate 106 are observed by the alignment scopes 123a and 123b. The alignment scopes 123a and 123b can measure the amounts of displacement of the alignment marks 126.

Note that

0a, 0b: the alignment scope position references

Xa, Xb: the amounts of displacement of the alignment mark 126 measured by the alignment scopes 123a and 123b, respectively (an outward direction from the substrate with reference to the alignment scope position references 0a and 0b as origins is determined as the positive direction)

Lwaf: the distance between the alignment marks 126

Then, when obtaining the substrate surface temperature, the equations (1) to (6) described above can be employed in the same manner.

Hence, using equation (6), a substrate surface temperature Tt is calculated as:

Tt=((Lscp+Xa+Xb)/Lwaf0−1)/ρwaf+T0w+Jst*R (6)

In this embodiment, heat drifts in the substrate 106 in a direction opposite to that in the first and second embodiments. Therefore, although the heat fluxes Jst and Jwaf shown in FIG. 2 become negative, equations (1) to (6) can be employed in the same manner.

### Fourth Embodiment

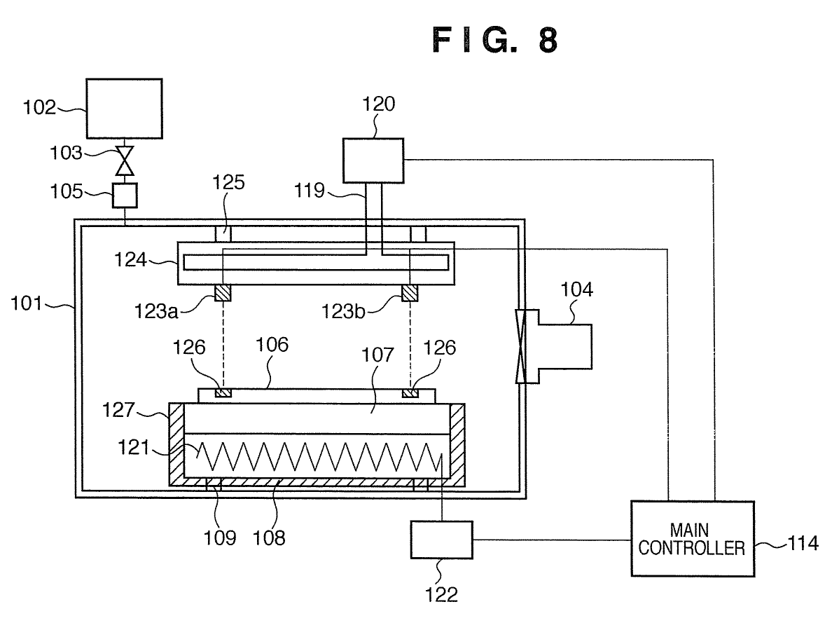

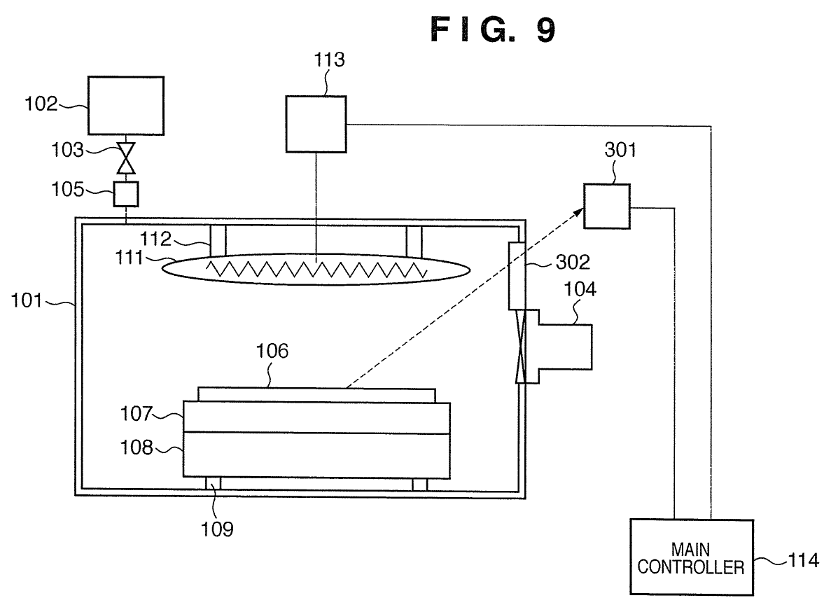

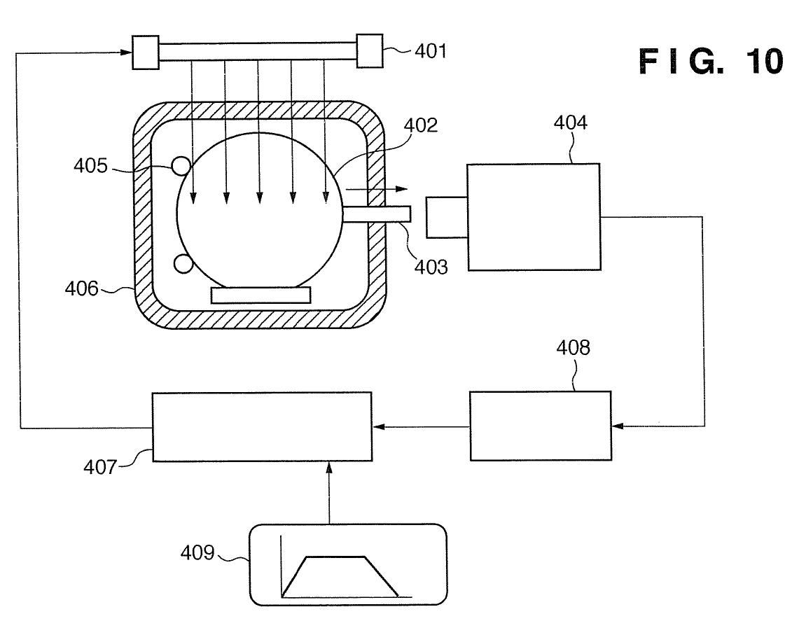

FIG. 8 schematically shows the arrangement of a thermal CVD apparatus according to the fourth embodiment of the present invention.

In the fourth embodiment, a heat-insulating material 127 which covers an electrostatic chuck 107 and a substrate stage 108 is added to the arrangement of FIG. 6. The substrate stage 108 serves as a substrate support body and is provided with a heater 121. Heat from the heater 121 almost entirely flows through a substrate 106.

With this arrangement, a heat flux Jwaf flowing through the substrate 106 becomes sufficiently equal to the energy supplied to the heater 121.

Accordingly, the heat flux Jwaf can be expressed as:

Jwaf=Pw/S (9)

where

Pw: the energy [J/s] supplied to the heater 121

S: the area [m²] of the substrate 106 Therefore, using equations (1) to (6) and (9), a substrate surface temperature Tt is calculated as:

Tt=((Lscp+Xa+Xb)/Lwaf0−1)/ρwaf+T0w+(Pw/S)*R (10)

As is apparent from the above equation (10), this embodiment is advantageous in that it does not require the heat flux sensor 110 which is necessary in the apparatus of FIG. 6.

Further, referring to the above embodiments, for example, when glass is used as the base material of the substrate, the coefficient of linear expansion is at least approximately 3E-6. Assuming that the substrate has a length of 1 m, if the substrate length can be measured with an error of approximately 1 μm, a temperature at this measurement can be obtained with an error of as small as approximately 0.3° C.

When the substrate is made of glass, the thermal conductivity is approximately 1 W/(m·K). When the substrate has a thickness of 2 mm, its heat resistance is approximately 20K·cm²/W. If a heat flux of 1 W/cm² flows at this time, a temperature difference of 20K occurs between the upper and lower surfaces of the substrate, and a temperature difference of 10K occurs between the neutral plane and upper surface of the substrate. Even in this case, the temperature distribution in the substrate can be calculated by measuring the heat flux.

As the material of a high-temperature polysilicon TFT substrate, silica glass is employed. When the substrate is made of silica glass, the thermal conductivity is approximately 1.4 W/(m·K). When the substrate has a thickness of 1 mm, its heat resistance is 7K·cm²/W; when 2 mm, 14K·cm²/W. If a heat flux of 1 W/cm² flows at this time, when the substrate thickness is 1 mm, a temperature difference of 7K occurs between the upper and lower surfaces of the substrate, and a temperature difference of 3.5K occurs between the neutral plane and upper surface of the substrate. Similarly, when the substrate thickness is 2 mm, a temperature difference of 14K occurs between the upper and lower surfaces of the substrate, and a temperature difference of 7K occurs between the neutral plane and upper surface of the substrate.

When the substrate is made of polyether sulfone (PES) which is expected as the material of a bendable TFT, the thermal conductivity is approximately 0.18 W/(m·K). When the substrate has a thickness of 1 mm, its heat resistance is 56K·cm²/W; when 0.3 mm, 17K·cm²/W. If a heat flux of 1 W/cm² flows at this time, when the substrate thickness is 1 mm, a temperature difference of 56K occurs between the upper and lower surfaces of the substrate, and a temperature difference of 28K occurs between the neutral plane and upper surface of the substrate. Similarly, when the substrate thickness is 0.3 mm, a temperature difference of 17K occurs between the upper and lower surfaces of the substrate, and a temperature difference of 8.5K occurs between the neutral plane and upper surface of the substrate.

The value of the heat resistance can be calculated by an equation expressed as t/C where C is the thermal conductivity (W/cm·K) and t is the thickness (cm) of the material.

As described above, when the average temperature of the substrate is calculated on the basis of the expansion amount of the substrate and the relative temperature difference between the neutral plane and the upper surface of the substrate is calculated on the basis of the heat flux in the substrate, the surface temperature of the substrate can be obtained accurately.

As described above, according to the present invention, the surface temperature of the substrate can be measured very accurately without adversely affecting the process such as film formation that should originally be performed in noncontact with the substrate. As a result, the reproducibility and stability of the process can improve. This is effective in improving the quality of the formed film and the yield, thus reducing the cost.

As the noncontact type sensor which is prepared in the present invention to obtain the surface temperature in the noncontact manner, a distance measuring sensor employing a general laser or an alignment scope provided with an inexpensive image processor can be used. Thus, the measurement system can be formed at a greatly lower cost than in a case that uses a radiation thermometer.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-051931, filed Mar. 3, 2008, which is hereby incorporated by reference herein in its entirety.

What is claimed is:

1. A substrate surface temperature measurement method comprising:
a measurement step of measuring an expansion amount of a substrate; and
a surface temperature calculation step of calculating a temperature of a neutral plane of the substrate using the expansion amount of the substrate, calculating a temperature difference between the neutral plane and a surface of the substrate from a heat flux and heat resistance of the substrate, and obtaining a temperature of the surface of the substrate using the temperature difference and the temperature of the neutral plane of the substrate.

2. The method according to claim 1, wherein in the surface temperature calculation step, the temperature of the neutral plane of the substrate is calculated on the basis of the expansion amount, an initial length of the substrate which is measured in advance, a temperature at which the initial length is measured, and a coefficient of linear expansion of the substrate.

3. The method according to claim 1, wherein in the measurement step, the expansion amount of the substrate is measured from an amount of displacement of the substrate from a plurality of reference points thereon.

4. The method according to claim 3, wherein the amount of displacement is measured by a plurality of sensors.

5. The method according to claim 4, wherein the sensors comprise a noncontact type sensor.

6. The method according to claim 4, wherein the plurality of sensors are fixed to one support body.

7. The method according to claim 6, wherein in the measurement step, an expansion amount of the support body is calculated by measuring a temperature thereof, and the amount of displacement detected by the sensors is corrected using the expansion amount of the support body.

8. The method according to claim 6, wherein a refrigerant circulates in the support body.

9. The method according to claim 3, wherein the amount of displacement of the substrate from the plurality of reference points thereon is obtained by observing an edge surface of the substrate.

10. The method according to claim 3, wherein in the measurement step, the amount of displacement of the substrate from the plurality of reference points thereon is obtained by observing a mark on the substrate.

11. The method according to claim 1, wherein in the surface temperature calculation step, a heat flux in the substrate is obtained by measuring a heat flux of a substrate support body that supports the substrate.

12. The method according to claim 1, wherein when a support body that supports the substrate is provided with a heater which heats the substrate, in the surface temperature calculation step, the substrate support body provided with the heater is covered with a heat-insulating material, and a heat flux in the substrate is calculated from an energy supplied to the heater.

13. A substrate processing apparatus comprising:
heating means for heating a substrate;
control means for controlling said heating means;
expansion amount measurement means for measuring an expansion amount of the substrate; and
heat flux measurement means for measuring a heat flux in the substrate,
wherein said control means calculates a temperature of a neutral plane of the substrate using the expansion amount measured by said expansion amount measurement means, calculates a temperature difference between the neutral plane and an upper surface of the substrate from the heat flux measured by said heat flux measurement means and a heat resistance, obtaining a temperature of the upper surface of the substrate using the temperature difference and the temperature of the neutral plane of the substrate, and controls said heating means on the basis of the temperature of the upper surface.

14. A substrate processing apparatus comprising:
a substrate support body which supports a substrate;
substrate heating means provided to said substrate support body;
heat-insulating means for covering said substrate support body;
control means for controlling said substrate heating means; and
expansion amount measurement means for measuring an expansion amount of the substrate,
wherein said control means
calculates a temperature of a neutral plane of the substrate using the expansion amount measured by said expansion amount measurement means,
calculates a heat flux in the substrate from an energy supplied to said heating means, and
calculates a temperature difference between the neutral plane and an upper surface of the substrate from the calculated heat flux and a heat resistance, obtains a temperature of the upper surface of the substrate using the temperature difference and the temperature of the neutral plane of the substrate, and controls said heating means on the basis of the temperature of the upper surface.

15. The apparatus according to claim 13, wherein said control means calculates the temperature of the neutral plane of the substrate on the basis of the expansion amount, an initial length of the substrate which is measured in advance, a temperature at which the initial length is measured, and a coefficient of linear expansion of the substrate.

16. The apparatus according to claim 14, wherein said control means calculates the temperature of the neutral plane of the substrate on the basis of the expansion amount, an initial length of the substrate which is measured in advance, a temperature at which the initial length is measured, and a coefficient of linear expansion of the substrate.

17. The apparatus according to claim 13, wherein said expansion amount measurement means measures the expansion amount of the substrate from an amount of displacement of the substrate from a plurality of reference points thereon.

18. The apparatus according to claim 14, wherein said expansion amount measurement means measures the expansion amount of the substrate from an amount of displacement of the substrate from a plurality of reference points thereon.

19. The apparatus according to claim 17, wherein said expansion amount measurement means comprises a plurality of sensors which measure the amount of displacement.

20. The apparatus according to claim 18, wherein said expansion amount measurement means comprises a plurality of sensors which measure the amount of displacement.

21. The apparatus according to claim 19, wherein said sensors comprise a noncontact type sensor.

22. The apparatus according to claim 20, wherein said sensors comprise a noncontact type sensor.

23. The apparatus according to claim 19, wherein said plurality of sensors are fixed to one support body.

24. The apparatus according to claim 20, wherein said plurality of sensors are fixed to one support body.

25. The apparatus according to claim 23, further comprising support body temperature detection means for measuring a temperature of the support body,
wherein said control means calculates an expansion amount of the support body using the detected temperature thereof, and
corrects the amount of displacement detected by said sensors using the expansion amount of the support body.

26. The apparatus according to claim 24, further comprising support body temperature detection means for measuring a temperature of the support body,
wherein said control means calculates an expansion amount of the support body using the detected temperature thereof, and
corrects the amount of displacement detected by said sensors using the expansion amount of the support body.

27. The apparatus according to claim 23, further comprising means for circulating a refrigerant in the support body.

28. The apparatus according to claim 24, further comprising means for circulating a refrigerant in the support body.

29. The apparatus according to claim 19, wherein said expansion amount measurement means obtains the amount of displacement of the substrate from the plurality of reference points thereon by observing an edge surface of the substrate.

30. The apparatus according to claim 20, wherein said expansion amount measurement means obtains the amount of displacement of the substrate from the plurality of reference points thereon by observing an edge surface of the substrate.

31. The apparatus according to claim 19, wherein said expansion amount measurement means obtains the amount of displacement of the substrate from the plurality of reference points thereon by observing a mark on the substrate.

32. The apparatus according to claim 20, wherein said expansion amount measurement means obtains the amount of displacement of the substrate from the plurality of reference points thereon by observing a mark on the substrate.

33. The apparatus according to claim 13, further comprising heat flux detection means for measuring a heat flux in the substrate by measuring a heat flux of a substrate support body that supports the substrate.

34. A semiconductor device manufacturing method comprising a step of measuring a surface temperature of a substrate using a substrate surface temperature measurement method according to claim 1.
